(19) United States
(12) Patent Application Publication
(10) Pub. No.: US 2023/0239560 A1
(43) Pub. Date: Jul. 27, 2023

(54) CAMERA MODULE

(71) Applicant: Samsung Electro-Mechanics Co., Ltd., Suwon-si (KR)

(72) Inventors: Ah Hyeon IM, Suwon-si (KR); Jun Sup SHIN, Suwon-si (KR); Kyeong Jun KIM, Suwon-si (KR); Po Chul KIM, Suwon-si (KR); Jae Hyuk KIM, Suwon-si (KR)

(73) Assignee: Samsung Electro-Mechanics Co., Ltd., Suwon-si (KR)

(21) Appl. No.: 17/865,577

(22) Filed: Jul. 15, 2022

(30) Foreign Application Priority Data
Jan. 25, 2022 (KR) 10-2022-0010755

(51) Int. Cl. H04N 5/225; G02B 7/18; G02B 7/09; H02K 5/24; H05K 1/18

(52) U.S. Cl. CPC H04N 5/2257; G02B 7/1805; G02B 7/09; H02K 5/24; H05K 1/181; H05K 2201/10121

(57) ABSTRACT

A camera module includes a housing having an internal space, a printed circuit board disposed in the housing, and a reflective module disposed in the internal space of the housing and comprising a reflective member configured to change a path of incident light, and a reflective holder supporting the reflective member; and a noise prevention unit disposed on either the housing or the printed circuit board and configured to prevent the reflective holder from contacting the housing.

### CROSS-REFERENCE TO RELATED APPLICATIONS

This application claims benefit under 35 USC 119(a) of Korean Patent Application No. 10-2022-0010755 filed on Jan. 25, 2022, in the Korean Intellectual Property Office, the entire disclosure of which is incorporated herein by reference for all purposes.

### BACKGROUND

### 1. Field

This application relates to a camera module.

### 2. Description of Related Art

Recently, camera modules have been installed as a basic feature in portable electronic devices such as tablet personal computers (PCs), laptop computers, and other types of portable computers, as well as smartphones, and an autofocusing (AF) function, an optical image stabilization (OIS) function, a zoom function, and other functions have been added to camera modules for mobile terminals.

Such a camera module is provided with an actuator that directly moves a lens module or indirectly moves a reflective module including a reflective member for optical image stabilization. In addition, the actuator may generally move or rotate the lens module or the reflective module in various directions with a driving force by a magnet and a coil.

In addition to driving by the actuator, the lens module or the reflective module may rotate or move inside a housing due to shaking of the camera module in a state where power is not applied to the actuator.

Since a space between elements inside the camera module needs to be very narrow for miniaturization of the camera module, as the lens module and the reflective module move in the space inside the housing, there is a risk that the lens module and the reflective module may collide with a fixture inside the camera module.

In particular, since the reflective member (e.g., a prism) provided in the reflective module has a relatively large weight, a large impact may occur when the reflection member collides with the fixture inside the camera module during the movement or rotation. There is a risk that the reflective module may be damaged due to such an impact, and there is a risk that a loud impact sound (noise and strange sound) may be repeatedly generated.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, a camera module includes a housing having an internal space; a printed circuit board disposed in the housing; a reflective module disposed in the internal space of the housing and including a reflective member configured to change a path of incident light, and a reflective holder supporting the reflective member; and a noise prevention unit disposed on either the housing or the printed circuit board and configured to prevent the reflective holder from contacting the housing.

The noise prevention unit may include a frame having a rectangular plate shape, and a damper disposed on the frame.

The damper may be made of an elastic material.

The noise prevention unit may be disposed on an internal surface of the housing facing a bottom surface of the reflective holder.

The noise prevention unit may be disposed on a surface of the printed circuit board facing a bottom surface of the reflective member.

The noise prevention unit may include a frame having a rectangular plate shape, and a damper disposed on the frame and made of an elastic material.

The noise prevention unit may be disposed below an edge side portion of a bottom surface of the reflective holder.

The noise prevention unit may be disposed below an edge side portion of the reflective holder on one side of the reflective holder, and the camera module further may include another noise prevention unit disposed below another edge side portion of the reflective holder on an opposite side of the reflective holder.

In another general aspect, a camera module includes a housing having an internal space; a reflective module disposed in the internal space of the housing and including a reflective member configured to change a path of incident light, and a reflective holder supporting the reflective member; a damper unit disposed on the housing and facing a surface of the reflective holder on one side of the reflective member; and a first noise prevention unit disposed on the reflective holder and including a protrusion extending from the surface of the reflective holder facing the damper unit.

The camera module may further include another damper unit disposed on the housing and facing another surface of the reflective member on an opposite side of the reflective member, wherein the first noise prevention unit may further include another protrusion extending from the other surface of the reflective holder facing the other damper unit.

The damper unit may include a mounting member disposed on the housing, and a damper member disposed on the mounting member.

The reflective holder may be configured to be movable relative to the housing, and the protrusion and the damper member may be aligned with each other in a movement direction of the reflective holder so that the protrusion contacts the damper member when the reflective holder moves in the movement direction.

The camera module may further include a printed circuit board disposed in the housing; and a second noise prevention unit configured to prevent the reflective holder from contacting the housing, wherein the second noise prevention unit may be disposed on either the housing or the printed circuit board.

The second noise prevention unit may include a frame having a rectangular plate shape, and a damper disposed on the frame.

The second noise prevention unit may be disposed on an internal surface of the housing facing a bottom surface of the reflective holder.

The second noise prevention unit may be disposed on a surface of the printed circuit board facing a bottom surface of the reflective holder.

In another general aspect, a camera module includes a housing having an internal space; a reflective module disposed in the internal space of the housing and including a reflective member configured to change a path of incident light, and a reflective holder supporting the reflective member and configured to be movable relative to the housing; and a noise prevention unit disposed in the housing and configured to limit a movement of the reflective holder.

The noise prevention unit may include a first noise prevention unit configured to limit a movement of the reflective holder in a first movement direction; and a second noise prevention unit configured to limit a movement of the reflective holder in second movement direction opposite to the first movement direction.

The camera module may further include a damper unit disposed on the housing and including a damper member extending toward a surface of the reflective holder, wherein the first noise prevention unit may include a protrusion extending from the surface of the reflective holder toward the damper unit and aligned with the damper member so that the protrusion contacts the damper member when the reflective holder moves by a predetermined distance in the first movement direction.

The second noise prevention unit may be disposed on the housing so that the reflective holder contacts the second noise prevention unit when the reflective holder moves by a predetermined distance in the second movement direction.

The camera module may further include a printed circuit board disposed in the housing, wherein the second noise prevention unit may be disposed on the printed circuit board so that the reflective holder contacts the second noise prevention unit when the reflective holder moves by a predetermined distance in the second movement direction.

Other features and aspects will be apparent from the following detailed description, the drawings, and the claims.

### BRIEF DESCRIPTION OF DRAWINGS

FIG. 1 is a perspective view of an example of a camera module.

FIG. 2 is an exploded perspective view of the camera module of FIG. 1.

FIG. 3 is a cross-sectional view of a portion of the camera module in which an example of a noise prevention unit is installed.

FIG. 4 is a plan view of the portion of FIG. 3 in which the noise prevention unit is installed.

FIG. 5 is a cross-sectional view of a portion of the camera module in which another example of a noise prevention unit is installed.

FIG. 6 is a plan view illustrating the portion of FIG. 5 in which the noise prevention unit is installed.

FIG. 7 is a cross-sectional view of a portion of the camera module in which another example of a noise prevention unit is installed.

FIG. 8 is a perspective view of a reflective holder in the portion of FIG. 7 on which the noise prevention unit is installed.

FIG. 9 is an exploded perspective view of a portion of the camera module in which another example of a noise prevention unit is installed.

FIG. 10 is a plan view of a portion of the camera module in which another example of a noise prevention unit is installed.

FIG. 11 is a cross-sectional view of the portion of FIG. 10 in which the noise prevention unit is installed.

FIG. 12 is a plan view of a portion of the camera module in which another example of a noise prevention unit is installed.

FIG. 13 is a cross-sectional view of the portion of FIG. 12 in which the noise prevention unit is installed.

Throughout the drawings and the detailed description, the same reference numerals refer to the same elements. The drawings may not be to scale, and the relative sizes, proportions, and depictions of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of functions and constructions that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Use herein of the term “may” in describing the various examples, e.g., as to what an example may include or implement, means that at least one example exists in which such a feature is included or implemented, but not all examples are limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated by 90° or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

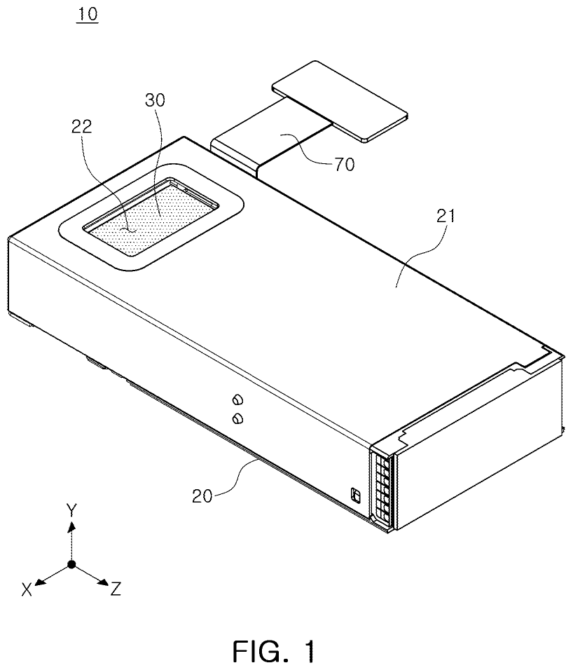

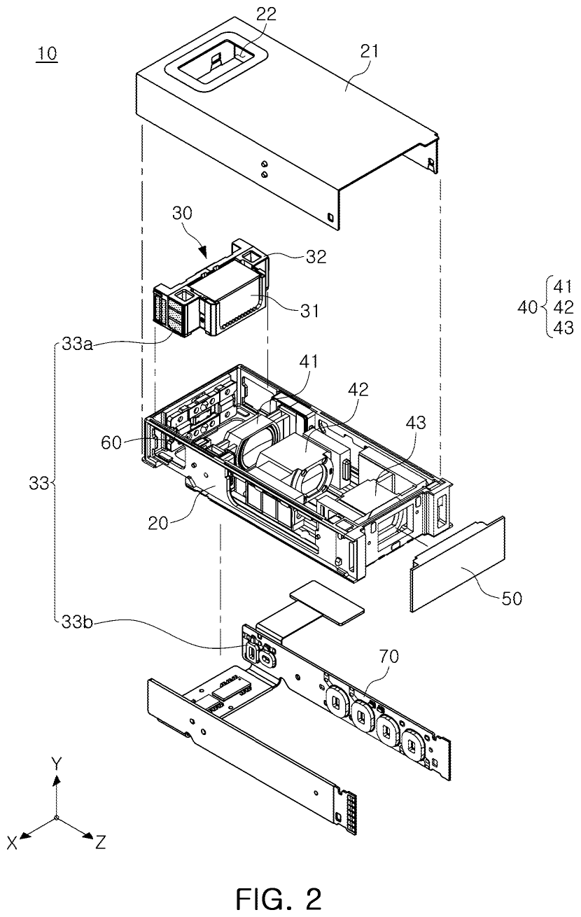

FIG. 1 is a perspective view of an example of a camera module, and FIG. 2 is an exploded perspective view of the camera module of FIG. 1.

The camera module 10 includes a housing 20 having an internal space, a reflective module 30, a lens module 40, and an image sensor module 50 that are provided in the internal space of the housing 20, and an upper cover 21 covering an upper portion of the housing 20.

The reflective module 30 is configured to change a traveling direction of incident light. A traveling direction of light originating from a subject (not illustrated) outside the camera module 10 may be changed to be directed toward the lens module 40 through the reflective module 30. For example, a path of light that is incident in a thickness direction (e.g., a Y-axis direction) of the camera module 10 through an opening 22 formed in the upper cover 21 may be changed to approximately coincide with an optical axis direction (e.g., a Z-axis direction) of the lens module 40 by the reflective module 30. To change the path of the light, the reflective module 30 may include a reflective member 31 that reflects light. In the camera module 10, the reflective member 31 included in the reflective module 30 may rotate about a rotation shaft or move in various directions to perform an optical image stabilization (OIS) function.

The camera module 10 may be provided with a guide member 60 that guides the movement of the reflective module 30. The guide member 60 is provided adjacent to the reflective module 30, and may guide the reflective module 30 to rotate around a certain shaft or to move in a certain direction. For example, the guide member 60 may be provided with a ball member (not illustrated) or a pivot member (not illustrated) forming the rotation shaft of the reflective module 30, or may be provided with a rail member (not illustrated) constituting a movement path of the reflective module 30, or may be provided with any other member guiding the movement of the reflective module 30.

The lens module 40 may include one or more lens barrels 41, 42, and 43 housing one or more lenses through which light whose traveling direction has been changed by the reflective module 30 passes. As the reflective module 30 moves in the optical axis direction (the Z-axis direction) of the lens barrels 41, 42, and 43, or a spacing of the lens barrels 41, 42, and 43 is adjusted, an auto focusing (AF) or zoom function may be implemented. Alternatively, the camera module 10 may perform the optical image stabilization function by moving one or more of the lens barrels 41, 42, and 43.

The lens module 40 may include a fixed lens barrel 41 fixed with respect to the housing 20 and movable lens barrels 42 and 43 that move with respect to the housing 20. One or more movable lens barrels 42 and 43 may be provided.

An image sensor module 50 including an image sensor for converting light passing through the lens module into an electrical signal may be provided behind the lens module 40. The image sensor module 50 may further include an optical filter (not illustrated) that filters light incident through the lens module 40.

In the camera module 10, the reflective module 30 may be provided in front of the lens module 40 and the image sensor module 50 may be provided behind the lens module 40 with respect to the lens module 40 in the internal space of the housing 20. Accordingly, light incident from a subject outside the camera module 10 may be incident on the image sensor module 50 through the reflective module 30 and the lens module 40 in sequence.

The image sensor module 50 may be electrically connected to a printed circuit board 70 to transmit image information to the outside of the camera module 10 in the form of an electrical signal.

The reflective module 30 may be housed in the housing 20 of the camera module 10 to change the path of the incident light. For example, as illustrated in FIG. 2, the reflective module 30 may be housed adjacent to the lens module 40 in the housing 20 to change a path of light incident in the thickness direction (the Y-axis direction) of the camera module 10 to the optical axis direction (the Z-axis direction) of the lens module 40.

The reflective module 30 may include the reflective member 31 capable of changing a path of light, a reflective holder 32 supporting the reflective member 31, and a driver 33 moving the reflective holder 32.

The reflective member 31 of the reflective module 30 may refract or reflect the incident light to change the traveling path of the light. For example, a traveling path of light incident on the reflective member 31 in a first direction (the Y-axis direction) may be changed to a second direction (the Z-axis direction) intersecting the first direction by the reflective member 31. The reflective member 31 may be provided to reflect or refract the incident light. For example, the reflective member 31 may change the traveling path of the light incident from the external subject to the optical axis direction (the Z-axis direction) of the lens module 40. The reflective member 31 may be a mirror or a prism that reflects light, but is not limited thereto. As the reflective member 31, any reflective member may be used as long as it may change the path of light. However, for convenience of description, it is assumed that the reflective member 31 has a prism shape in the following description.

The reflective holder 32 movably supports the reflective member 31. That is, the reflective member 31 is supported by the reflective holder 32 and may move within a predetermined range. For example, the reflective holder 32 may rotate about a rotation axis (e.g., an axis parallel to the X axis) passing through the reflective holder 32 or may reciprocate within a certain range. Accordingly, the reflective member 31 supported by the reflective holder 32 may rotate or reciprocate according to the movement of the reflective holder 32.

At least some surfaces of the reflective holder 32 are provided with the driver 33 that moves the reflective holder 32. For example, as illustrated in FIG. 2, the driver 33 may be provided at both end portions of the reflective holder 32 in one direction (e.g., in the X-axis direction). The driver 33 may be an electromagnetic actuator including a magnet 33a and a coil 33b, but is not limited thereto. As the driver 32, any driver may be used as long as it may move the reflective holder 32 within a certain range.

The reflective module 30 may further include a position detector (not illustrated) that detects the amount of movement of the reflective holder 32.

The reflective module 30 may rotate or move the reflective holder 32 and the reflective member 31 supported by the reflective holder 32 inside the housing 20 through a driving force generated by the driver 33, thereby performing the optical image stabilization function.

Since the reflective holder 32 is provided to be movable, there is a risk that the reflective holder 32 collides with other members adjacent to the reflective module 30 while moving. For example, when the reflective module 30 is provided in the housing 20 of the camera module 10, as the reflective module 30 moves inside the housing 20, there is a risk that the reflective module 30 collides with an internal surface of the housing 20. In addition, when the camera module 10 or the housing 20 shakes up, down, left, and right in a situation where power is not applied to the driver 33, the reflective module 30 provided in the internal space of the housing 20 may randomly collide with the internal surface of the housing 20 due to its relative motion inside the housing 20. There is a risk that the reflective module 30 may be damaged due to the impact generated by the collision, or a noise (strange sound) may be generated due to the collision.

To prevent this, the camera module 10 may be provided with a noise prevention unit. Hereinafter, examples of the noise prevention unit will be described.

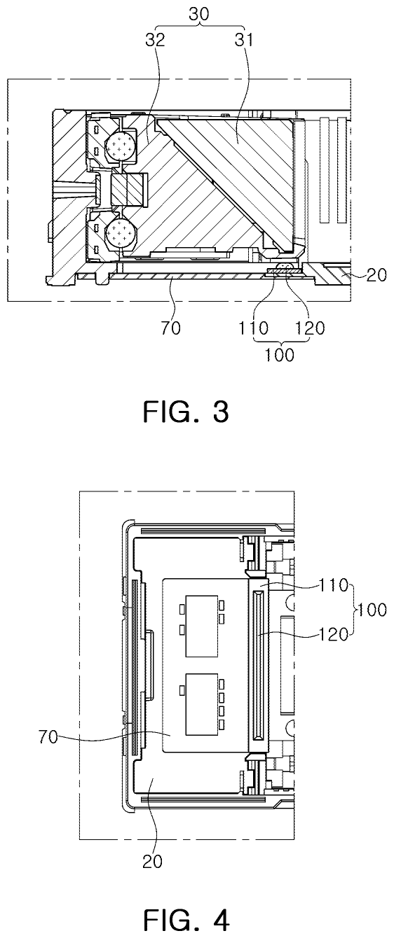

FIG. 3 is a cross-sectional view of a portion of the camera module in which an example of a noise prevention unit is installed, and FIG. 4 is a plan view of the portion of FIG. 3 in which the noise prevention unit is installed.

Referring to FIGS. 3 and 4, a noise prevention unit 100 is installed on the internal surface of the housing 20 so as to be disposed below the reflective holder 32. As an example, the noise prevention unit 100 may include a frame 110 having a rectangular plate shape and a damper 120 installed on the frame 110. The frame 110 may be made of the same material as the housing 20, and may be bonded to the housing 20 by an adhesive. As an example, the damper 120 may have a rectangular shape. The damper 120 may have a smaller size than the frame 110 and may be made of an elastic material. The noise prevention unit 100 limits the movement of the reflective holder 32 when the reflective holder 32 moves or rotates in the downward direction in FIG. 3.

Since the noise prevention unit 100 is installed in the housing 20 so as to be disposed below the reflective holder 32, the generation of the impact sound due to the contact between the bottom surface of the reflective holder 32 and the internal surface of the housing 20 may be prevented.

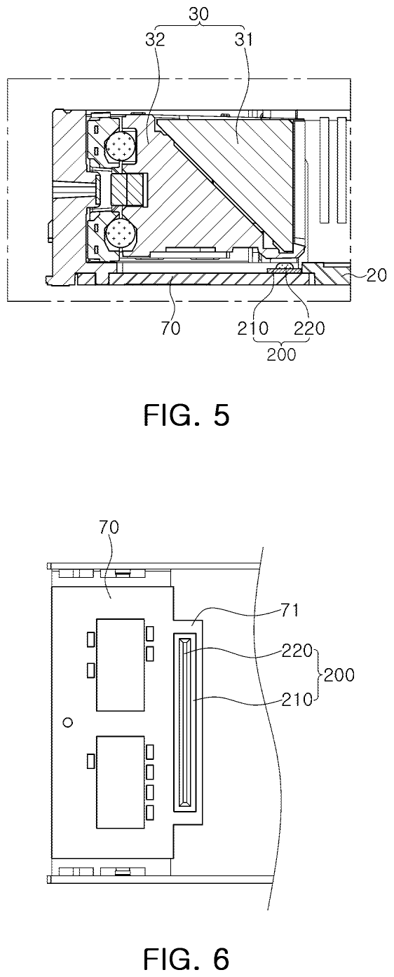

FIG. 5 is a cross-sectional view of a portion of the camera module in which another example of a noise prevention unit is installed, and FIG. 6 is a plan view of the portion of FIG. 5 in which the noise prevention unit is installed.

Referring to FIGS. 5 and 6, a noise prevention unit 200 is installed on the upper surface of the printed circuit board 70 so as to be disposed below the reflective holder 32. As an example, the noise prevention unit 200 may include a frame 210 having a rectangular plate shape and a damper 220 installed on the frame 210. The damper 220 may have a rectangular shape. The printed circuit board 70 may include a protrusion 71 on which the noise prevention unit 200 is installed. The noise prevention unit 200 may be installed on the protrusion 71 of the printed circuit board 70 so as to be disposed below the reflective holder 32. The noise prevention unit 200 may be bonded to the protrusion 71 of the printed circuit board 70 by an adhesive. The damper 220 may have a smaller size than the frame 210 and may be made of an elastic material.

Since the noise prevention unit 200 is installed on the protrusion of the printed circuit board 70 so as to be disposed below the reflective holder 32, the generation of the impact sound due to the contact between the bottom surface of the reflective holder 32 and the internal surface of the housing 20 may be prevented.

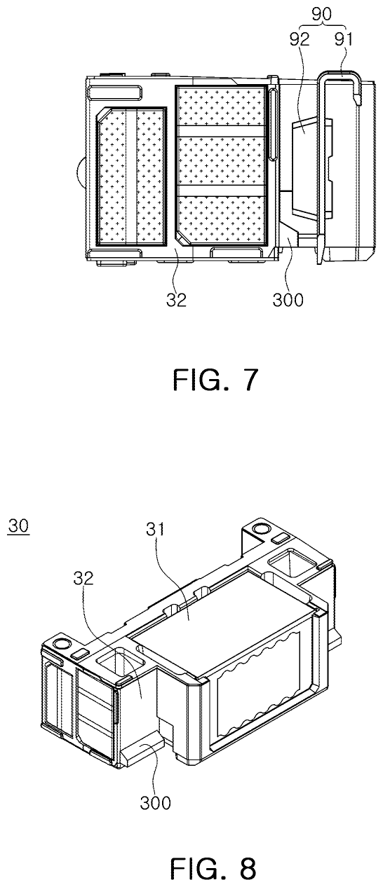

FIG. 7 is a cross-sectional view of a portion of the camera module in which another example of a noise prevention unit is installed, and FIG. 8 is a perspective view of a reflective holder in the portion of FIG. 7 on which the noise prevention unit is installed.

Referring to FIGS. 7 and 8, a noise prevention unit 300 may be disposed on a front surface of the reflective holder 32 so as to be disposed on both sides of the reflective member 31. As an example, the noise prevention unit 300 may be formed as a protrusion extending from the front surface of the reflective holder 32. The noise prevention unit 300 may extend from a lower end portion of the front surface of the reflective holder 32.

A damper unit 90 is installed in the housing 20. As an example, the damper unit 90 may include a mounting member 91 fixedly installed on the housing 20 and a damper member 92 installed on the mounting member 91. The noise prevention unit 300 and the damper member 92 are aligned with each other in a movement direction of the reflective holder 32 so that the noise prevention unit 300 contacts the damper member 92 when the reflective holder 32 moves in the movement direction. Thus, the noise prevention unit 300 limits the movement of the reflective holder 32 when the reflective holder 32 moves or rotates in the upward direction in FIG. 7.

Since the noise prevention unit 300 contacts the damper member 92 when the reflective holder 32 moves, the generation of the impact sound generated when the reflective holder 32 moves may be reduced.

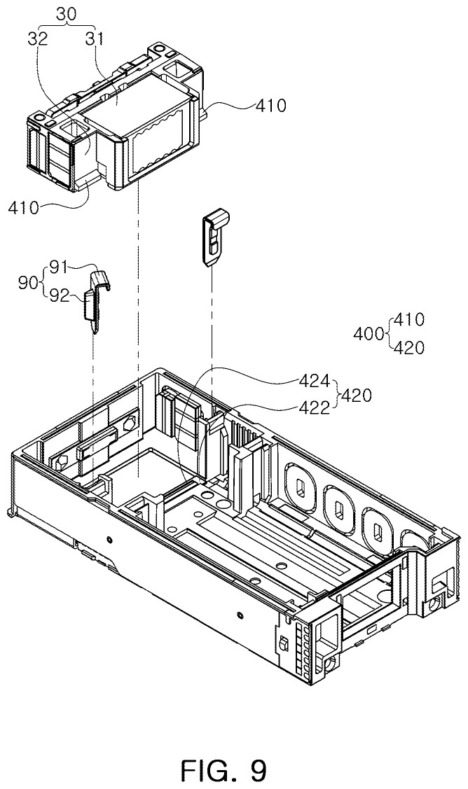

FIG. 9 is an exploded perspective view of the camera module in which another example of a noise prevention unit is installed.

Referring to FIG. 9, a noise prevention unit 400 may include a first noise prevention unit 410 installed on the reflective holder 32 and a second noise prevention unit 420 installed on the printed circuit board 70.

The first noise prevention unit 410 may be disposed on the front surface of the reflective holder 32 so as to be disposed on both sides of the reflective member 31. As an example, the first noise prevention unit 410 may be formed as a protrusion extending from the front surface the reflective holder 32. The first noise prevention unit 410 may extend from the lower end portion of the front surface of the reflective holder 32.

A damper unit 90 is installed in the housing 20. As an example, the damper unit 90 may include a mounting member 91 fixedly installed on the housing 20 and a damper member 92 installed on the mounting member 91. The noise prevention unit 300 and the damper member 92 are aligned with each other in a movement direction of the reflective holder 32 so that the noise prevention unit 300 contacts the damper member 92 when the reflective holder 32 moves in the movement direction.

Since the noise prevention unit 300 contacts the damper member 92 when the reflective holder 32 moves, the generation of the impact sound generated when the reflective holder 32 moves may be reduced.

The second noise prevention unit 420 is installed on the upper surface of the printed circuit board 70 (not shown in FIG. 9, but see FIGS. 5 and 6) so as to be disposed below the reflective holder 32. As an example, the second noise prevention unit 420 may include a frame 422 having a rectangular plate shape and a damper 424 installed on the frame 422. The damper 424 may have a rectangular shape. The printed circuit board 70 may include a protrusion 71 (not shown in FIG. 9, but see FIGS. 5 and 6) on which the second noise prevention unit 420 is installed. The second noise prevention unit 420 may be installed on the protrusion 71 of the printed circuit board 70 so as to be disposed below the reflective holder 32. The second noise prevention unit 420 may be bonded to the protrusion 71 of the printed circuit board 70 by an adhesive. The damper 424 may have a smaller size than the frame 422 and may be made of an elastic material.

Since the second noise prevention unit 420 is installed on the protrusion 71 of the printed circuit board 70 so as to be disposed below the reflective holder 32, the generation of the impact sound due to the contact between the bottom surface of the reflective holder 32 and the internal surface of the housing 20 may be prevented.

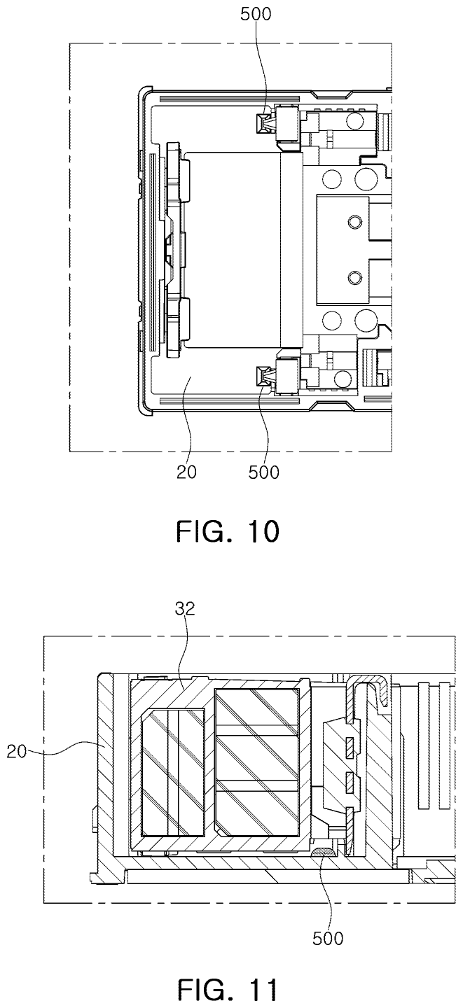

FIG. 10 is a plan view of a cross section of a camera module in which another example of a noise prevention unit is installed, and FIG. 11 is a cross-sectional view of the portion of FIG. 10 in which the noise prevention unit is installed.

Referring to FIGS. 10 and 11, a noise prevention unit 500 is installed on the internal surface of the housing 20 so as to be disposed below the reflective holder 32. The noise prevention unit 500 may be disposed under an edge side portion of the bottom surface of the reflective holder 32. As an example, two noise prevention units 500 may be provided under opposite edge side portions of the bottom surface of the reflective holder 32. However, the invention is not limited thereto, and more than two noise prevention units 500 may be provided under the bottom surface of the reflective holder 32. As an example, the noise prevention unit 500 may be a damper installed on the internal surface of the housing. The noise prevention unit 500 may have a rectangular shape. The noise prevention unit 500 may be bonded to the housing 20 by an adhesive. For example, the noise prevention unit 500 may be made of an elastic material.

Since the noise prevention unit 500 is installed on the internal surface of the housing 20 so as to be disposed below the reflective holder 32, the generation of the impact sound due to the contact between the bottom surface of the reflective holder 32 and the internal surface of the housing 20 may be prevented.

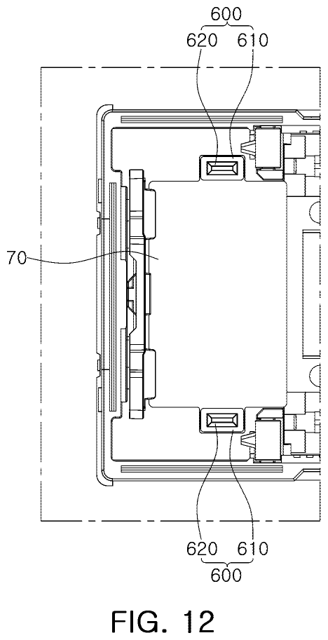

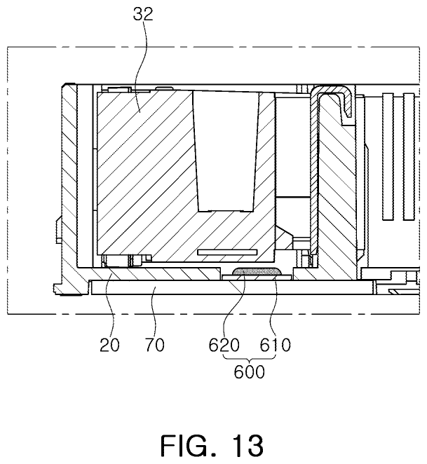

FIG. 12 is a plan view of the camera module in which another example of a noise prevention unit is installed, and FIG. 13 is a cross-sectional view of the portion of FIG. 12 in which the noise prevention unit is installed.

Referring to FIGS. 12 and 13, a noise prevention unit 600 is installed on the printed circuit board 70 so as to be disposed below the reflective holder 32. As an example, the noise prevention unit 600 may include a frame 610 having a rectangular plate shape and a damper 620 installed on the frame 610. The frame 610 may be bonded to the printed circuit board 70 by an adhesive. As an example, the damper 620 may have a rectangular shape. The damper 620 may have a smaller size than the frame 610 and may be made of an elastic material.

Since the noise prevention unit 600 is installed on the printed circuit board 70 so as to be disposed below the reflective holder 32, the generation of the impact sound due to the contact between the bottom surface of the reflective holder 32 and the internal surface of the housing 20 may be prevented.

As described above, the examples of the noise prevention unit described above make it possible to minimize the impact generated when a reflective module collides with a fixture adjacent to the reflective module, such as an internal surface of a housing of the camera module.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and are not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A camera module comprising:
a housing having an internal space;
a printed circuit board disposed in the housing;
a reflective module disposed in the internal space of the housing and comprising a reflective member configured to change a path of incident light, and a reflective holder supporting the reflective member; and
a noise prevention unit disposed on either the housing or the printed circuit board and configured to prevent the reflective holder from contacting the housing.

2. The camera module of claim 1, wherein the noise prevention unit comprises a frame having a rectangular plate shape, and a damper disposed on the frame.

3. The camera module of claim 2, wherein the damper is made of an elastic material.

4. The camera module of claim 3, wherein the noise prevention unit is disposed on an internal surface of the housing facing a bottom surface of the reflective holder.

5. The camera module of claim 1, wherein the noise prevention unit is disposed on a surface of the printed circuit board facing a bottom surface of the reflective member.

6. The camera module of claim 5, wherein the noise prevention unit comprises a frame having a rectangular plate shape, and a damper disposed on the frame and made of an elastic material.

7. The camera module of claim 1, wherein the noise prevention unit is disposed below an edge side portion of a bottom surface of the reflective holder.

8. The camera module of claim 1, wherein the noise prevention unit is disposed below an edge side portion of the reflective holder on one side of the reflective holder, and
the camera module further comprises another noise prevention unit disposed below another edge side portion of the reflective holder on an opposite side of the reflective holder.

9. A camera module comprising:
a housing having an internal space;
a reflective module disposed in the internal space of the housing and comprising a reflective member configured to change a path of incident light, and a reflective holder supporting the reflective member;
a damper unit disposed on the housing and facing a surface of the reflective holder on one side of the reflective member; and
a first noise prevention unit disposed on the reflective holder and comprising a protrusion extending from the surface of the reflective holder facing the damper unit.

10. The camera module of claim 9, further comprising another damper unit disposed on the housing and facing another surface of the reflective member on an opposite side of the reflective member,
wherein the first noise prevention unit further comprises another protrusion extending from the other surface of the reflective holder facing the other damper unit.

11. The camera module of claim 9, wherein the damper unit comprises a mounting member disposed on the housing, and a damper member disposed on the mounting member.

12. The camera module of claim 11, wherein the reflective holder is configured to be movable relative to the housing, and
the protrusion and the damper member are aligned with each other in a movement direction of the reflective holder so that the protrusion contacts the damper member when the reflective holder moves in the movement direction.

13. The camera module of claim 9, further comprising:
a printed circuit board disposed in the housing; and
a second noise prevention unit configured to prevent the reflective holder from contacting the housing,
wherein the second noise prevention unit is disposed on either the housing or the printed circuit board.

14. The camera module of claim 13, wherein the second noise prevention unit comprises a frame having a rectangular plate shape, and a damper disposed on the frame.

15. The camera module of claim 14, wherein the second noise prevention unit is disposed on an internal surface of the housing facing a bottom surface of the reflective holder.

16. The camera module of claim 14, wherein the second noise prevention unit is disposed on a surface of the printed circuit board facing a bottom surface of the reflective holder.

17. A camera module comprising:
a housing having an internal space;
a reflective module disposed in the internal space of the housing and comprising a reflective member configured to change a path of incident light, and a reflective holder supporting the reflective member and configured to be movable relative to the housing; and
a noise prevention unit disposed in the housing and configured to limit a movement of the reflective holder.

18. The camera module of claim 17, wherein the noise prevention unit comprises:
a first noise prevention unit configured to limit a movement of the reflective holder in a first movement direction; and
a second noise prevention unit configured to limit a movement of the reflective holder in second movement direction opposite to the first movement direction.

19. The camera module of claim 18, further comprising a damper unit disposed on the housing and comprising a damper member extending toward a surface of the reflective holder,
wherein the first noise prevention unit comprises a protrusion extending from the surface of the reflective holder toward the damper unit and aligned with the damper member so that the protrusion contacts the damper member when the reflective holder moves by a predetermined distance in the first movement direction.

20. The camera module of claim 18, wherein the second noise prevention unit is disposed on the housing so that the reflective holder contacts the second noise prevention unit when the reflective holder moves by a predetermined distance in the second movement direction.

21. The camera module of claim 18, further comprising a printed circuit board disposed in the housing,
wherein the second noise prevention unit is disposed on the printed circuit board so that the reflective holder contacts the second noise prevention unit when the reflective holder moves by a predetermined distance in the second movement direction.
